(19) United States
(12) Patent Application Publication
(10) Pub. No.: US 2025/0162100 A1
(43) Pub. Date: May 22, 2025

(54) POLISHING HEAD AND POLISHING APPARATUS

(71) Applicant: EBARA CORPORATION, Tokyo (JP)

(72) Inventors: Makoto KASHIWAGI, Tokyo (JP); Mao FUJISAWA, Tokyo (JP)

(21) Appl. No.: 18/840,847

(22) PCT Filed: Feb. 15, 2023
(86) PCT No.: PCT/JP2023/005147

§ 371 Date: Aug. 22, 2024

(30) Foreign Application Priority Data
Mar. 1, 2022 (JP) 2022-030585

(51) Int. Cl. B24B 37/20

(52) U.S. Cl. CPC B24B 37/20

(57) ABSTRACT

The present invention relates to a polishing head for pressing a polishing tape against a substrate, such as a wafer. The present invention further relates to a polishing apparatus for polishing a substrate with such a polishing head. The polishing head (10) includes: a pressing member (12) configured to press a polishing tape (2) against the substrate (W); an actuator (15) configured to move the pressing member (12) in a predetermined pressing direction (CL) and apply a pressing force to the pressing member (12); and a tilt adjustment mechanism (40) configured to adjust tilt of the pressing member (12) with respect to the pressing direction (CL). The tilt adjustment mechanism (40) is configured to tilt the pressing member (12) with respect to the pressing direction (CL) and maintain an angle of the tilted pressing member (12).

### TECHNICAL FIELD

The present invention relates to a polishing head for pressing a polishing tape against a substrate, such as a wafer. The present invention further relates to a polishing apparatus for polishing a substrate with such a polishing head.

### BACKGROUND ART

In recent years, devices, such as memory circuits, logic circuits, and image sensors (e.g., CMOS sensors) have been becoming more highly integrated. In a process of manufacturing these devices, foreign matter, such as fine particles and dust, may adhere to the devices. The foreign matter adhered to the devices may cause short circuits of interconnects and may cause circuit malfunctions. Therefore, in order to improve reliability of the devices, it is necessary to clean a wafer on which the devices are formed and remove the foreign matter from the wafer.

Foreign matter, such as fine particles and dust as mentioned above, may adhere to a back surface (non-device surface) of a wafer. If such foreign matter adheres to the back surface of the wafer, the wafer may be separated away from a stage reference surface of an exposure device, causing a front surface of the wafer to tilt relative to the stage reference surface. As a result, patterning and focal length may be shifted. To prevent such problems, it is necessary to remove the foreign matter from the back surface of the wafer.

Therefore, as shown in FIGS. 15 and 16, a polishing apparatus is used to polish a back surface of a wafer with a polishing tape. FIG. 15 is a top view of a conventional polishing apparatus, and FIG. 16 is a side view of the conventional polishing apparatus shown in FIG. 15. In this polishing apparatus, a plurality of rollers 500 hold a periphery of a wafer W, and the rollers 500 themselves rotate to thereby rotate the wafer W. A polishing tape 502 is disposed on the back surface of the wafer W. A predetermined tension is applied to the polishing tape 502, while the polishing tape 502 advances in a direction indicated by arrow Z.

Multiple pressing members 505 are arranged in a diameter direction of the wafer W. These pressing members 505 are configured to press the polishing tape 502 against the back surface of the wafer W, thereby polishing the back surface of the wafer W. The polishing tape 502 pressed against the back surface of the wafer W can remove foreign matter from the back surface of the wafer W.

However, as shown in FIG. 17, when the polishing tape 502 is pressed against the wafer W by the pressing member 505, the wafer W is bent upward. When the wafer W is bent in an arc shape, the polishing tape 502 is not pressed uniformly, and as a result, a polishing rate of the wafer W becomes non-uniform.

Thus, as shown in FIG. 18, there is proposed a polishing apparatus having a universal joint 509 that supports the pressing member 505 so that the pressing member 505 can tilt. Since the universal joint 509 enables the pressing member 505 to follow the bending of the wafer W, it is expected that the pressing member 505 can uniformly press the polishing tape 502 against the wafer W.

### CITATION LIST

### Patent Literature

Patent document 1: Japanese laid-open patent publication No. 2021-122895

### SUMMARY OF INVENTION

### Technical Problem

However, as shown in FIG. 19, the pressing member 505 may be forced to tilt due to the polishing tape 502 moving in the direction indicated by the arrow Z, and the pressing member 505 may not be able to follow the bending of the wafer W. The polishing tape 502 pressed against the back surface of the wafer W by the pressing member 505 moves in the direction indicated by the arrow Z, causing friction between the polishing tape 502 and the wafer W and between the polishing tape 502 and the pressing member 505. The friction between the polishing tape 502 and the pressing member 505 causes the pressing member 505 to rotate around the universal joint 509 as a fulcrum, and tilt in the direction indicated by the arrow Z. As a result, the pressing member 505 cannot uniformly press the polishing tape 502 against the wafer W.

Therefore, the present invention provides a polishing head capable of pressing a polishing tape against a substrate, such as a wafer, with a uniform force, and further provides a polishing apparatus including such a polishing head.

### Solution to Problem

In an embodiment, there is provided a polishing head for polishing a substrate, comprising: a pressing member configured to press a polishing tape against the substrate; an actuator configured to move the pressing member in a predetermined pressing direction and apply a pressing force to the pressing member; and a tilt adjustment mechanism configured to adjust tilt of the pressing member with respect to the pressing direction, the tilt adjustment mechanism being configured to tilt the pressing member with respect to the pressing direction and maintain an angle of the tilted pressing member.

In an embodiment, the tilt adjustment mechanism has a first support shaft perpendicular to an advancing direction of the polishing tape and is configured to tilt the pressing member about the first support shaft.

In an embodiment, the tilt adjustment mechanism comprises: a base member supporting the first support shaft; a tilt member coupled to the first support shaft and tiltable about the first support shaft; and a plurality of screws that are screwed into a plurality of threaded holes formed in the tilt member, the plurality of screws being in contact with the base member.

In an embodiment, the plurality of screws are disposed at both sides of the first support shaft.

In an embodiment, the polishing head further comprises a pressing-member holder that holds the pressing member, the tilt adjustment mechanism further including a second support shaft that is perpendicular to the first support shaft, the pressing-member holder being tiltable about the second support shaft.

In an embodiment, there is provided a polishing apparatus comprising: a substrate holder configured to hold a substrate; and the polishing head configured to polish the substrate.

### Advantageous Effects of Invention

Since the pressing member is inclined in advance at a fixed angle by the tilt adjustment mechanism, the pressing member can press the polishing tape uniformly against the bent substrate. As a result, the polishing tape can polish the substrate uniformly.

### BRIEF DESCRIPTION OF DRAWINGS

FIG. 1 is a perspective view showing an embodiment of a polishing head for polishing a wafer by pressing a polishing tape, which is an example of a polishing tool, against a surface of the wafer which is an example of a substrate;

FIG. 2 is a cross-sectional view of the polishing head shown in FIG. 1;

FIG. 3 is a schematic diagram showing a pressing member and a pressing-member holder when removed from a tilt adjustment mechanism;

FIG. 4 is an exploded perspective view of the tilt adjustment mechanism;

FIG. 5 is a horizontal cross-sectional view of the tilt adjustment mechanism;

FIG. 6 is a cross-sectional view showing the pressing-member holder and the pressing member tilted to a predetermined angle by the tilt adjustment mechanism;

FIG. 7 is a cross-sectional view showing the pressing member pressing the polishing tape against the wafer when the pressing-member holder and pressing member are tilted at a fixed angle by the tilt adjustment mechanism;

FIG. 8 is a perspective view showing another embodiment of the polishing head;

FIG. 9 is a schematic view showing the pressing member and pressing-member holder of the polishing head shown in FIG. 8 when removed from the tilt adjustment mechanism;

FIG. 10 is an exploded perspective view of the tilt adjustment mechanism;

FIG. 11 is a side view showing an embodiment of a polishing apparatus;

FIG. 12 is a top view of the polishing apparatus shown in FIG. 11;

FIG. 13 is a perspective view showing another embodiment of a polishing head;

FIG. 14 is a cross-sectional view showing the polishing tape being pressed against an edge portion of a wafer by the pressing member with the pressing-member holder and pressing member shown in FIG. 13 tilted at a fixed angle by the tilt adjustment mechanism;

FIG. 15 is a top view of a conventional polishing apparatus;

FIG. 16 is a side view of the conventional polishing apparatus shown in FIG. 15;

FIG. 17 is a schematic diagram explaining how a wafer is bent upward by a pressing member;

FIG. 18 is a schematic diagram of a conventional polishing apparatus having a universal joint; and

FIG. 19 is a schematic diagram explaining how the pressing member is forced to tilt due to a polishing tape.

### DESCRIPTION OF EMBODIMENTS

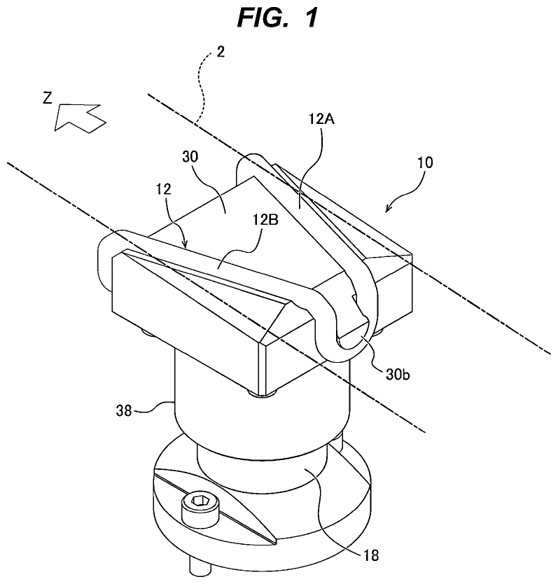

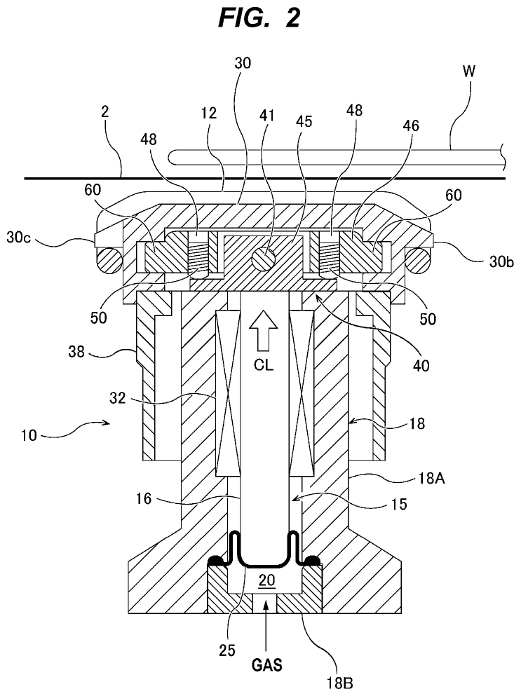

Hereinafter, embodiments of the present invention will be described with reference to the drawings. FIG. 1 is a perspective view showing an embodiment of a polishing head 10 for pressing a polishing tape 2, which is an example of a polishing tool, against a surface of a wafer W, which is an example of a substrate, to polish the wafer W. FIG. 2 is a cross-sectional view of the polishing head 10 shown in FIG. 1. The polishing head 10 of this embodiment is disposed under the wafer W and the polishing tape 2, and is disposed so as to press the polishing tape 2 against a back surface of the wafer W from a back side of the polishing tape 2.

The polishing head 10 includes a pressing member 12 configured to press the polishing tape 2 against the wafer W, an actuator 15 configured to move the pressing member 12 in a predetermined pressing direction indicated by an arrow CL to apply a pressing force to the pressing member 12, and a housing 18 in which the actuator 15 is disposed. The actuator 15 includes a movable shaft 16 coupled to the pressing member 12, and a partition membrane (diaphragm) 25 forming a pressure chamber 20 between an end of the movable shaft 16 and the housing 18. The movable shaft 16 and the partition membrane 25 are disposed in the housing 18.

The polishing head 10 further includes a pressing-member holder 30 configured to hold the pressing member 12. The pressing-member holder 30 is coupled to the movable shaft 16 and can move together with the movable shaft 16. The pressing member 12 has an annular shape as a whole, and the pressing member 12 is removably held by the pressing-member holder 30. The pressing-member holder 30 has a fitting groove (not shown) into which the pressing member 12 fits. The annular pressing member 12 is hung on the pressing-member holder 30, with the pressing member 12 elastically deformed while fitting into the fitting groove. The pressing member 12 of this embodiment has two tape-pressing surfaces 12A and 12B for pressing the polishing tape 2 against the wafer W.

The pressing member 12 is made of an elastic material. Examples of material constituting the pressing member 12 include rubber, such as fluororubber, silicone rubber, and ethylene propylene diene rubber. The pressing member 12 has a circular cross section. The pressing member 12 may be an O-ring. In this embodiment, the pressing-member holder 30 has protrusions 30b and 30c on its side surfaces. The protrusions 30b and 30c support the pressing member 12 in an elastically deformed state.

It is noted that the pressing member 12 is not limited to this embodiment, and may have other shape or may be made of other material. For example, the pressing member 12 may have only one tape-pressing surface for pressing the polishing tape 2 against the wafer W. In another example, the pressing member 12 may have a shape of a linearly extending blade or a curved blade instead of the annular shape.

As shown in FIG. 2, the movable shaft 16 is movable in its axial direction in the housing 18, and the movable shaft 16 can raise the pressing member 12 in the pressing direction indicated by the arrow CL. The pressing member 12 faces the back side of the polishing tape 2. When the movable shaft 16 raises the pressing member 12 in the pressing direction indicated by the arrow CL, the pressing member 12 comes into contact with the back side of the polishing tape 2. The pressing member 12 presses a polishing surface of the polishing tape 2 against the back surface of the wafer W to polish the back surface of the wafer W with the polishing tape 2. During polishing of the wafer W, the back side of the polishing tape 2 is supported by the pressing member 12. The back side of the polishing tape 2 is a surface opposite to the polishing surface having abrasive grains. During polishing of the wafer W, the polishing tape 2 is advanced in its longitudinal direction at a predetermined speed. Arrow Z in FIG. 1 represents the advancing direction of the polishing tape 2.

In this embodiment, the movable shaft 16 is configured as a ball spline shaft. A ball spline nut 32 is disposed in the housing 18, and the movable shaft 16 is supported by the ball spline nut 32 so as to be movable in the axial direction of the movable shaft 16. In one embodiment, the movable shaft 16 may be movably supported by an inner surface of the housing 18.

The housing 18 includes a housing body 18A having a space formed therein for accommodating the movable shaft 16, and a lid 18B for closing the space. The lid 18B is detachably fixed to the housing body 18A by a screw (not shown). The actuator 15 is configured to generate a pressing force for pressing the polishing tape 2 against the wafer W. The actuator 15 includes the movable shaft 16 and the partition membrane 25. The partition membrane 25 is in contact with an end (lower end) of the movable shaft 16, and an edge of the partition membrane 25 is sandwiched between the housing body 18A and the lid 18B. The partition membrane 25 is only in contact with the movable shaft 16, but is not fixed to the movable shaft 16.

The partition membrane 25 is made of a flexible material. Examples of material that can be used to form the partition membrane 25 include chloroprene rubber, fluororubber, and silicone rubber. The pressure chamber 20 is coupled to a compressed-gas supply line (not shown), so that compressed gas (e.g., compressed air) is supplied from the compressed-gas supply line into the pressure chamber 20.

The polishing head 10 further includes a tilt adjustment mechanism 40 configured to adjust a tilt of the pressing member 12 with respect to the moving direction CL of the pressing member 12 which is moved by the actuator 15. The pressing-member holder 30 is coupled to the tilt adjustment mechanism 40, and the pressing member 12 and the pressing-member holder 30 are coupled to the movable shaft 16 via the tilt adjustment mechanism 40. The tilt adjustment mechanism 40 is disposed between the movable shaft 16 and the pressing-member holder 30, and is housed in the pressing-member holder 30. The tilt adjustment mechanism 40, the pressing-member holder 30, and the pressing member 12 are moved together by the actuator 15. The tilt adjustment mechanism 40 is configured to tilt the pressing member 12 with respect to the moving direction CL and to maintain an angle of the tilted pressing member 12.

During polishing of the wafer W, the compressed gas, such as compressed air, is supplied into the pressure chamber 20. The pressure of the compressed gas in the pressure chamber 20 acts on the end (lower end) of the movable shaft 16 through the partition membrane 25, and elevates the movable shaft 16, the tilt adjustment mechanism 40, the pressing-member holder 30, and the pressing member 12. The polishing head 10 may further include a distance sensor configured to measure a movement distance of the movable shaft 16 relative to the housing 18. When polishing of the wafer W is to be terminated, the pressure chamber 20 is opened to the atmosphere, and as a result, the movable shaft 16 and the pressing member 12 are lowered by the weight of the movable shaft 16 and the tension of the polishing tape 2.

A skirt 38 is fixed to the pressing-member holder 30. This skirt 38 extends downward from the pressing-member holder 30 and surrounds an upper part of the housing 18. In this embodiment, the skirt 38 has a cylindrical shape, but may have other shape as long as the skirt 38 can surround the upper part of the housing 18. The skirt 38 can prevent liquid, such as pure water used in polishing of the wafer W, from entering the housing 18.

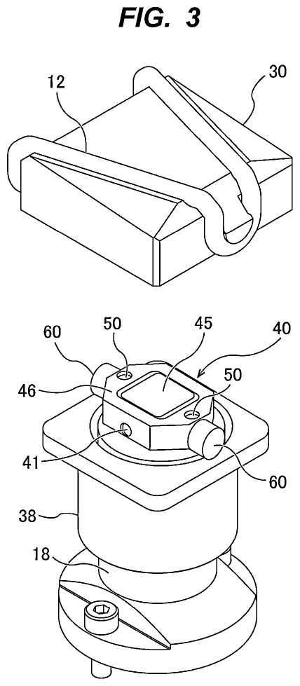

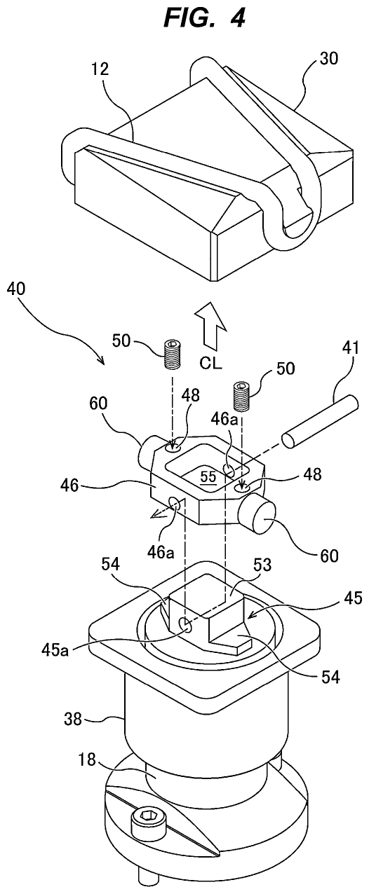

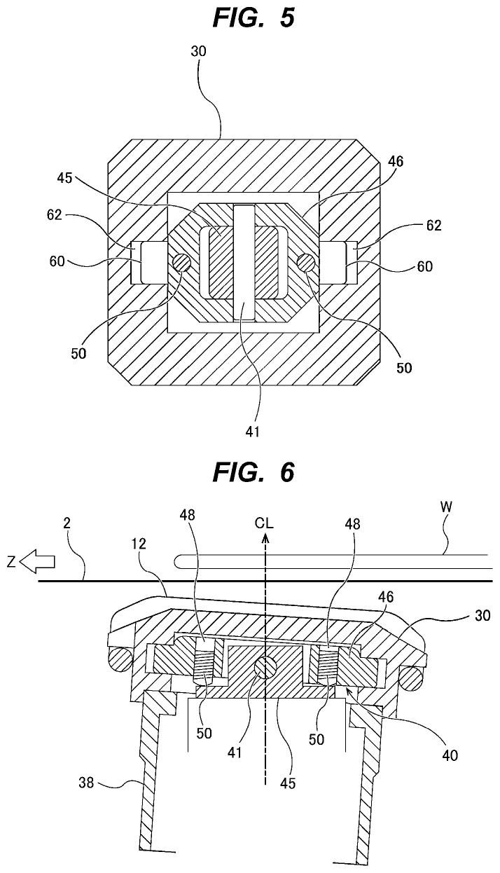

FIG. 3 is a schematic diagram showing a state in which the pressing member 12 and the pressing-member holder 30 are removed from the tilt adjustment mechanism 40, FIG. 4 is an exploded perspective view of the tilt adjustment mechanism 40, and FIG. 5 is a horizontal cross-sectional view of the tilt adjustment mechanism 40. As shown in FIGS. 3 and 4, the tilt adjustment mechanism 40 includes a first support shaft 41, a base member 45 that supports the first support shaft 41, a tilt member 46 coupled to the first support shaft 41 and can tilt about the first support shaft 41, and a plurality of screws 50 that are screwed into a plurality of threaded holes 48 provided in the tilt member 46.

The base member 45 is fixed to the upper end of the movable shaft 16 and can move together with the movable shaft 16. The first support shaft 41 is inserted into through-holes 46a formed in the tilt member 46 and a through-hole 45a formed in the base member 45. An extending direction of the first support shaft 41 is perpendicular to the moving direction CL of the pressing member 12 and perpendicular to the longitudinal direction of the polishing tape 2 (i.e., the advancing direction of the polishing tape 2). Therefore, the tilt member 46 can tilt (rotate) around the first support shaft 41. The pressing member 12 and the pressing-member holder 30 are coupled to the tilt member 46 and can tilt (rotate) together with the tilt member 46 around the first support shaft 41. In other words, the pressing member 12 and the pressing-member holder 30 can tilt in the advancing direction Z of the polishing tape 2 (i.e., the longitudinal direction of the polishing tape 2) shown in FIG. 1.

The multiple screws 50 have a function of maintaining the angle of the tilt member 46 tilted about the first support shaft 41, i.e., the angle of the tilted pressing member 12 and the tilted pressing-member holder 30. The multiple screws 50 are disposed at both sides of the first support shaft 41 and aligned along a direction perpendicular to the first support shaft 41. In other words, these screws 50 are aligned along the longitudinal direction of the polishing tape 2 (the advancing direction Z of the polishing tape 2 shown in FIG. 1).

The plurality of screws 50 are screwed into the plurality of threaded holes 48 formed in the tilt member 46. Each threaded hole 48 extends through the tilt member 46. The plurality of screws 50 protrude downward from the tilt member 46, and distal ends of the plurality of screws 50 are in contact with the base member 45. The base member 45 has a central portion 53 and two protruding portions 54 protruding from both sides of the central portion 53. The central portion 53 is disposed in a hollow space 55 formed in the center of the tilt member 46. The distal ends of the plurality of screws 50 are in contact with the two protruding portions 54, respectively. The tilt angle of the tilt member 46 about the first support shaft 41 can be changed by positions of the plurality of screws 50 relative to the tilt member 46. Furthermore, the distal ends of the plurality of screws 50 are in contact with the base member 45, so that the tilt angle of the tilt member 46 about the first support shaft 41 can be maintained (fixed).

The tilt adjustment mechanism 40 further includes second support shafts 60 perpendicular to the first support shaft 41. The pressing-member holder 30 is tiltable (rotatable) about the second support shafts 60. In this embodiment, the second support shafts 60 protrude from both sides of the tilt member 46 and engage with recesses 62 (see FIG. 5) formed in the pressing-member holder 30. The entire pressing-member holder 30 is supported by the second support shafts 60. The second support shafts 60 are provided to equalize the pressing force applied to the wafer W through the polishing tape 2 from the two tape-pressing surfaces 12A and 12B of the pressing member 12 on the pressing-member holder 30. In one embodiment, the second support shafts 60 may be omitted.

FIG. 6 is a cross-sectional view showing a state in which the pressing-member holder 30 and the pressing member 12 are tilted to a predetermined angle by the tilt adjustment mechanism 40. As can be seen from FIG. 6, the positions of the screws 50 relative to the tilt member 46 are different from each other in the advancing direction Z of the polishing tape 2 (the longitudinal direction of the polishing tape 2), and this allows the tilt member 46, the pressing-member holder 30, and the pressing member 12 to be tilted with respect to the pressing direction CL. The tilt member 46, the pressing-member holder 30, and the pressing member 12 are tilted in the direction along the advancing direction Z of the polishing tape 2 (the longitudinal direction of the polishing tape 2). The tilt angle of the tilt member 46, the pressing-member holder 30, and the pressing member 12 is determined by a difference in protruding amount of the plurality of screws 50 protruding from the tilt member 46 toward the base member 45 (more specifically, toward the protruding portions 54). In other words, a difference in a degree to which the screws 50 are screwed into the threaded holes 48 results in the difference in the protruding amount of these screws 50, and this difference in the protruding amount of the screws 50 determines the tilt angle of the tilt member 46, the pressing-member holder 30, and the pressing member 12.

The tilt angle of the tilt member 46, the pressing-member holder 30, and the pressing member 12 is maintained (fixed) by the contact of the plurality of screws 50 and the base member 45. The tilt angle of the tilt member 46, the pressing-member holder 30, and the pressing member 12 is determined in advance based on a polishing result of a previously polished wafer, etc. More specifically, the tilt angle of the tilt member 46, the pressing-member holder 30, and the pressing member 12 is an angle that allows the pressing member 12 to uniformly press the polishing tape 2 against the wafer (i.e., the polishing tape 2 can uniformly polish the wafer).

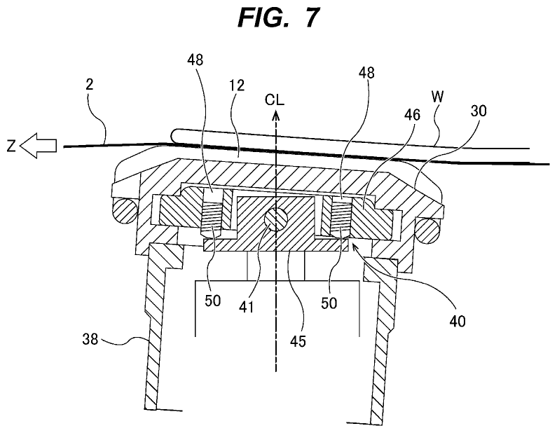

FIG. 7 is a cross-sectional view showing a state in which the polishing tape 2 is pressed against the wafer W by the pressing member 12 while the pressing-member holder 30 and the pressing member 12 are tilted at a fixed angle by the tilt adjustment mechanism 40. As shown in FIG. 7, when the polishing tape 2 is pressed against the wafer W by the pressing member 12, the wafer W is bent by the pressing force of the pressing member 12. Since the pressing member 12 is tilted in advance at a fixed angle by the tilt adjustment mechanism 40, the pressing member 12 can uniformly press the polishing tape 2 against the bent wafer W. As a result, the polishing tape 2 can polish the wafer W uniformly.

During polishing of the wafer W, as shown in FIG. 7, the polishing tape 2 advances in the direction indicated by the arrow Z while being tensioned. As the polishing tape 2 advances, friction occurs between the polishing tape 2 and the wafer W and between the polishing tape 2 and the pressing member 12. The friction between the polishing tape 2 and the pressing member 12 generates a torque of tilting the pressing member 12. Since the screws 50 of the tilt adjustment mechanism 40 can fix the tilt of the pressing member 12, even if the torque generated by the friction generated between the polishing tape 2 and the pressing member 12 is applied to the pressing member 12, the pressing member 12 can maintain its predetermined tilt angle.

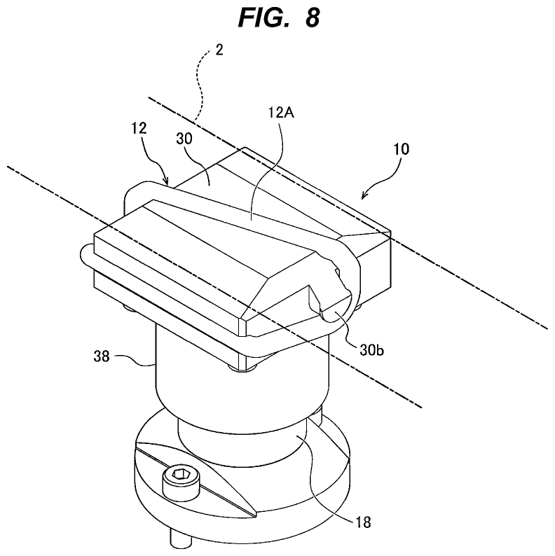

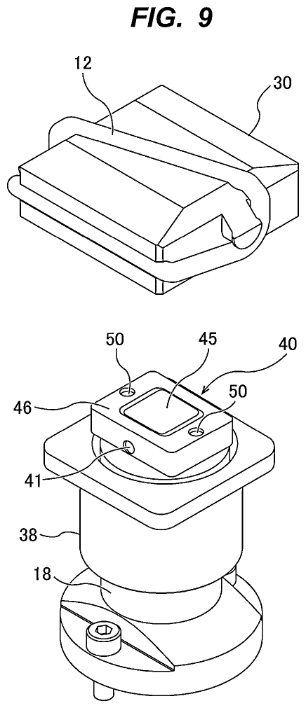

FIG. 8 is a perspective view showing another embodiment of a polishing head, FIG. 9 is a schematic view showing a pressing member 12 and a pressing-member holder 30 of the polishing head shown in FIG. 8 when removed from a tilt adjustment mechanism 40, and FIG. 10 is an exploded perspective view of the tilt adjustment mechanism 40. Configurations and operations of this embodiment that are not particularly described are the same as those of the embodiments described with reference to FIGS. 1 to 7, and therefore repeated descriptions will be omitted.

This embodiment is different from the embodiments described with reference to FIGS. 1 to 7 in that the pressing member 12 has only one tape-pressing surface 12A and the second support shafts 60 are not provided. Therefore, the tilt member 46, the pressing member 12, and the pressing-member holder 30 cannot tilt about an axis (corresponding to the second support shafts 60) perpendicular to the first support shaft 41.

According to the embodiment described with reference to FIGS. 8 to 10, the pressing member 12 is tilted in advance at a fixed angle by the tilt adjustment mechanism 40, so that the pressing member 12 can uniformly press the polishing tape 2 against the bent wafer W. As a result, the polishing tape 2 can polish the wafer W uniformly.

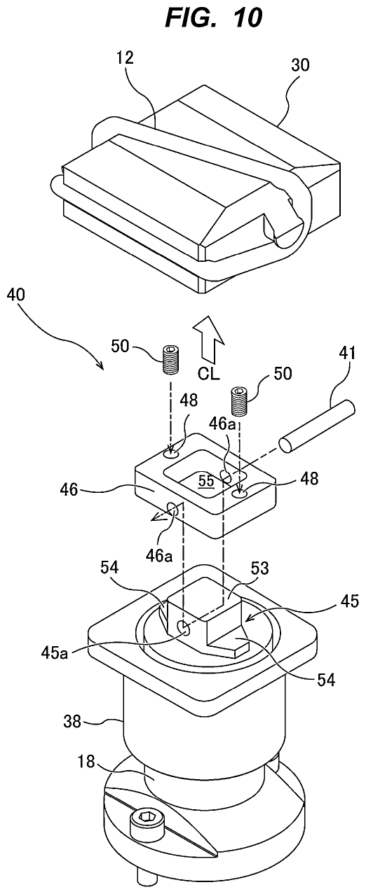

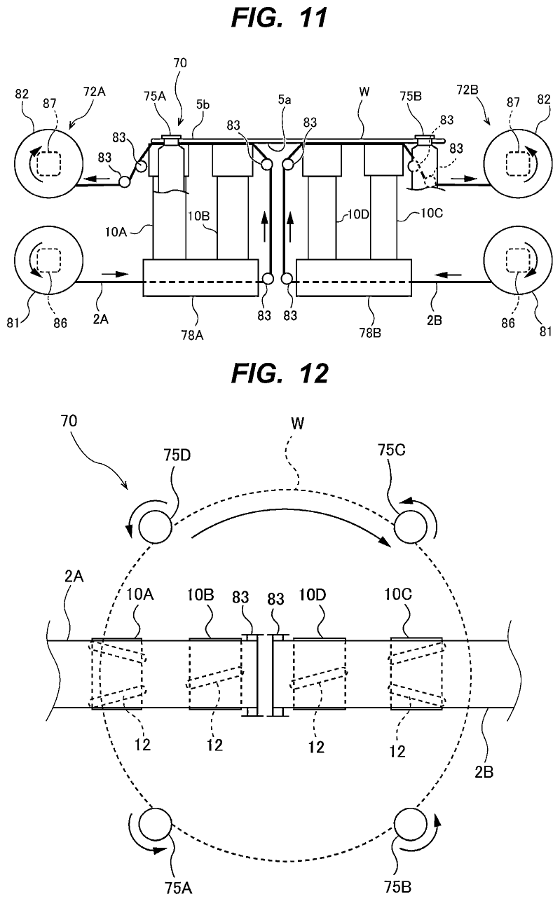

FIG. 11 is a side view showing an embodiment of a polishing apparatus, and FIG. 12 is a top view of the polishing apparatus shown in FIG. 11. The polishing apparatus shown in FIG. 11 and FIG. 12 includes a substrate holder 70 configured to hold and rotate a wafer W, a plurality of polishing heads 10A to 10D configured to bring polishing tapes 2A and 2B into contact with a first surface 5a of the wafer W held by the substrate holder 70 to polish the first surface 5a of the wafer W, a polishing-tape supply mechanism 72A configured to supply a polishing tape 2A to the polishing heads 10A and 10B and collect the polishing tape 2A from the polishing heads 10A and 10B, and a polishing-tape supply mechanism 72B configured to supply a polishing tape 2B to the polishing heads 10C and 10D and collect the polishing tape 2B from the polishing heads 10C and 10D.

The polishing heads 10A and 10C have the same configuration as the polishing head 10 described with reference to FIGS. 1 to 7, and the polishing heads 10B and 10D have the same configuration as the polishing head 10 described with reference to FIGS. 8 to 10. The polishing tapes 2A and 2B have the same configuration.

In this embodiment, the first surface 5a of the wafer W is a back surface of the wafer W on which no devices are formed or no devices are to be formed, i.e., a non-device surface. A second surface 5b of the wafer W opposite to the first surface 5a is a surface on which devices are formed or devices are to be formed, i.e., a device surface. In this embodiment, the wafer W is supported horizontally by the substrate holder 70 with the first surface 5a facing downward.

The substrate holder 70 includes a plurality of rollers 75A, 75B, 75C, and 75D configured to come into contact with the periphery of the wafer W, and a roller-rotating device (not shown) configured to rotate the rollers 75A to 75D at the same speed. In this embodiment, four rollers 75A to 75D are provided, while five or more rollers may be provided.

The polishing heads 10A and 10B are supported by a support member 78A, and the polishing heads 10C and 10D are supported by a support member 78B. The polishing heads 10A to 10D are disposed under the wafer W held by the substrate holder 70. These polishing heads 10A to 10D are arranged in the diameter direction of the wafer W. In this embodiment, four polishing heads 10A to 10D are provided, but the number of polishing heads is not limited to this embodiment. In one embodiment, a single polishing head may be provided.

The polishing-tape supply mechanisms 72A and 72B have the same configuration, and therefore the polishing-tape supply mechanism 72A will be described below. The polishing-tape supply mechanism 72A includes a tape supply reel 81 to which one end of the polishing tape 2A is coupled, a tape take-up reel 82 to which the other end of the polishing tape 2A is coupled, and a plurality of guide rollers 83 configured to guide an advancing direction of the polishing tape 2A. The tape supply reel 81 and the tape take-up reel 82 are coupled to reel motors 86 and 87, respectively.

When the tape take-up reel 82 is rotated in a direction indicated by arrow, the polishing tape 2A is advanced from the tape supply reel 81 to the tape take-up reel 82 via the polishing heads 10A and 10B. The polishing tape 2A is supplied over the polishing heads 10A and 10B such that a polishing surface of the polishing tape 2A faces the first surface 5a of the wafer W. The reel motor 86 applies a predetermined torque to the tape supply reel 81, thereby applying a tension to the polishing tape 2A. The reel motor 87 is controlled to allow the polishing tape 2A to advance at a constant speed. The speed at which the polishing tape 2A advances can be changed by changing a rotational speed of the tape take-up reel 82.

In one embodiment, the polishing apparatus may include a tape-advancing device configured to advance the polishing tape 2A in its longitudinal direction, in addition to the tape supply reel 81, the tape take-up reel 82, and the reel motors 86 and 87. In yet another embodiment, positions of the tape supply reel 81 and the tape take-up reel 82 may be reversed.

The wafer W is polished as follows. While the periphery of the wafer W is held by the plurality of rollers 75A to 75D, the rollers 75A to 75D are rotated to thereby rotate the wafer W. While the polishing tapes 2A and 2B are fed to the polishing heads 10A to 10D by the polishing-tape supply mechanisms 72A and 72B, the pressing members 12 of the polishing heads 10A to 10D, each of which is tilted in advance to a predetermined angle by the tilt adjustment mechanism 40 described above, press the polishing tapes 2A and 2B against the first surface 5a of the wafer W to polish the first surface 5a of the wafer W.

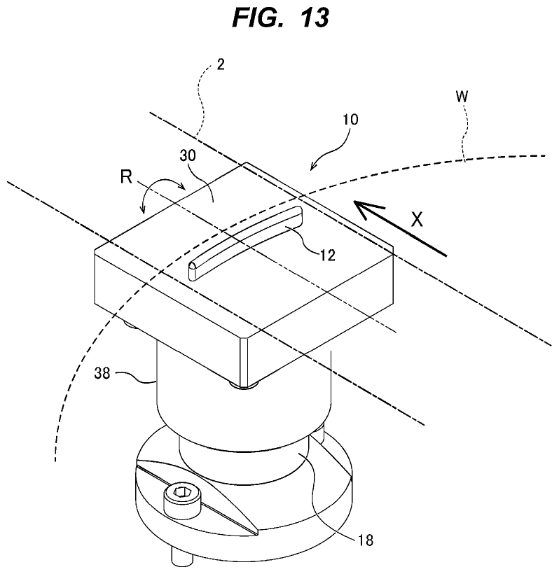

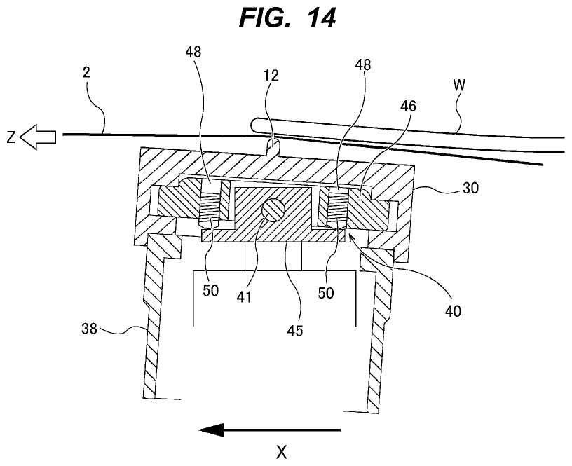

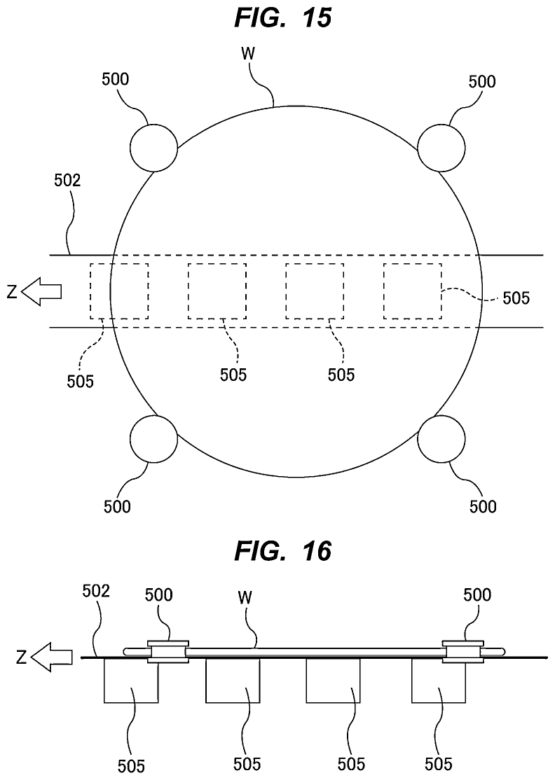

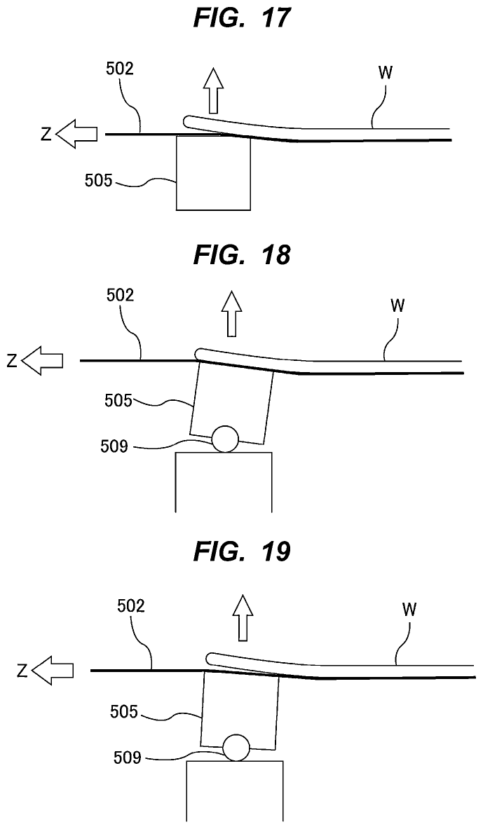

Although the embodiments of the tilt adjustment mechanism 40 described above are applied to the polishing head for polishing the back surface of the wafer, the tilt adjustment mechanism 40 can be applied to a polishing head having another configuration. For example, as shown in FIG. 13, the tilt adjustment mechanism 40 can be applied to a polishing head 10 for polishing an edge portion of a wafer. The polishing head 10 shown in FIG. 13 has a pressing member 12 that is curved along the edge portion of the wafer W. While the pressing member 12 is pressing the polishing tape 2 against the edge portion of the wafer W, the polishing head 10 moves outwardly in a radial direction of the wafer W as shown by arrow X. The movement of the polishing head 10 in the direction X is achieved by a polishing-head moving mechanism (not shown).

FIG. 14 is a cross-sectional view showing the pressing member 12 when pressing the polishing tape 2 against the edge portion of the wafer W, with the pressing-member holder 30 and the pressing member 12 shown in FIG. 13 tilted at a fixed angle by the tilt adjustment mechanism 40. The configuration of the tilt adjustment mechanism 40 is the same as that of the embodiments described with reference to FIGS. 3 to 7, and duplicated descriptions will be omitted.

As shown in FIG. 14, when the polishing tape 2 is pressed against the edge portion of the wafer W by the pressing member 12, the wafer W is bent by the pressing force of the pressing member 12. Since the pressing member 12 is tilted in advance at a fixed angle by the tilt adjustment mechanism 40, the pressing member 12 can uniformly press the polishing tape 2 against the edge portion of the bent wafer W. Furthermore, the tilt adjustment mechanism 40 allows the pressing member 12 to freely tilt about the axis R shown in FIG. 13 as indicated by arrow. As a result, the polishing tape 2 can uniformly polish the edge portion of the wafer W.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

### INDUSTRIAL APPLICABILITY

The present invention is applicable to a polishing head for pressing a polishing tape against a substrate, such as a wafer. The present invention is further applicable to a polishing apparatus for polishing a substrate using such a polishing head.

### REFERENCE SIGNS LIST

W wafer
2 polishing tape
2A, 2B polishing tape
5a first surface
5b second surface
10, 10A˜10D polishing head
12 pressing member
12A, 12B tape-pressing surface
15 actuator
16 movable shaft
18 housing
18A housing body
18B lid
20 pressure chamber
25 partition membrane
30 pressing-member holder
30b, 30c protrusion
32 ball spline nut
38 skirt
40 tilt adjustment mechanism
41 first support shaft
45 base member
45a through-hole
46 tilt member
46a through-hole
48 threaded hole
50 screw
53 central portion
54 protruding portion
55 hollow space
60 second support shaft
62 recess
70 substrate holder
72A, 72B polishing-tape supply mechanism
78A, 78B support member
81 tape supply reel
82 tape take-up reel
83 guide roller
86, 87 reel motor

1. A polishing head for polishing a substrate, comprising:
a pressing member configured to press a polishing tape against the substrate;
an actuator configured to move the pressing member in a predetermined pressing direction and apply a pressing force to the pressing member; and
a tilt adjustment mechanism configured to adjust tilt of the pressing member with respect to the pressing direction, the tilt adjustment mechanism being configured to tilt the pressing member with respect to the pressing direction and maintain an angle of the tilted pressing member.

2. The polishing head according to claim 1, wherein the tilt adjustment mechanism has a first support shaft perpendicular to an advancing direction of the polishing tape and is configured to tilt the pressing member about the first support shaft.

3. The polishing head according to claim 2, wherein the tilt adjustment mechanism comprises:
a base member supporting the first support shaft;
a tilt member coupled to the first support shaft and tiltable about the first support shaft; and
a plurality of screws that are screwed into a plurality of threaded holes formed in the tilt member, the plurality of screws being in contact with the base member.

4. The polishing head according to claim 3, wherein the plurality of screws are disposed at both sides of the first support shaft.

5. The polishing head according to claim 3, further comprising a pressing-member holder that holds the pressing member, the tilt adjustment mechanism further including a second support shaft that is perpendicular to the first support shaft, the pressing-member holder being tiltable about the second support shaft.

6. A polishing apparatus comprising:
a substrate holder configured to hold a substrate; and
a polishing head of claim 1 configured to polish the substrate.
